(19) United States
(12) Patent Application Publication
(10) Pub. No.: US 2004/0219737 A1
(43) Pub. Date: Nov. 4, 2004

(54) Method and apparatus for processing a workpiece with a plasma

(75) Inventor: Bill H. Quon, Brea, CA (US)

Correspondence Address: PILLSBURY WINTHROP, LLP, P.O. BOX 10500, MCLEAN, VA, 22102, US

(73) Assignee: Tokyo Electron Limited, Tokyo (JP)

(21) Appl. No.: 10/859,129

(22) Filed: Jun. 3, 2004

Related U.S. Application Data
(63) Continuation of application No. PCT/US02/37589, filed on Nov. 22, 2002.
(60) Provisional application No. 60/341,260, filed on Dec. 20, 2001.

(51) Int. Cl. H01L 21/8238

(52) U.S. Cl. 438/222

(57) ABSTRACT

A plasma processing apparatus includes a source gas injection device to inject a gaseous source material into a source region of the apparatus, a plasma generating device to transmit energy to the source material to generate a source plasma, and a process gas injection device to inject a gaseous process material into a process region of the apparatus. A magnetic filter assembly imposes a magnetic field generally between the source and process regions to control the flow of charged particles from the source plasma into the gaseous process material to generate a process plasma in the process region. A source electrode in contact with the source plasma controls the potential of the source plasma. An electrode supports a workpiece and generates a potential to attract charged particles from the process plasma toward the workpiece so that the charged particles strike the workpiece.

### CROSS REFERENCE TO RELATED APPLICATIONS

This is a continuation of PCT/US02/37589, filed Nov. 22, 2002 in the English language and designating the U.S., which, in turn, is based on and derives the benefit of the filing date of U.S. Provisional Application No. 60/341,260, filed Dec. 20, 2001, the contents of each of which are incorporated herein by reference in their entireties.

### BACKGROUND OF THE INVENTION

1. Field of the Invention

The present invention relates to plasma processing systems of the type that may be used, for example, for deposition of material on or the etching of material from a workpiece. The invention is more specifically directed to a method and apparatus for improving the properties of a plasma used to process a workpiece.

2. Background of the Invention

A process plasma is a collection of charged particles and radicals that may be used to process (that is, to remove material from or deposit material on) a workpiece. Process plasmas are used in the manufacture of integrated circuit (IC) devices, flat panel displays and other products. Process plasmas may be used, for example, to etch (i.e., remove) material from or to sputter (i.e., deposit) material on a workpiece in the form of, for example, a semiconductor wafer during IC fabrication.

A reactive process plasma may be generated by introducing a process gas into a plasma chamber and then ionizing and dissociating the gas. Plasma generated in the chamber strikes the workpiece during processing of the workpiece. The quality and efficiency of commercial plasma processing operations can be improved by improving the characteristics of the process plasma and the methods of generating the same.

### SUMMARY OF THE INVENTION

The present invention provides methods and apparatuses for processing a workpiece with a plasma. An illustrative embodiment of the apparatus includes a source gas injection device constructed and arranged to inject a gaseous source material into a source region of the apparatus and a plasma generating device mounted in plasma generating relation to the source region. The plasma generating device is constructed and arranged to transmit energy to a gaseous source material in the source region to generate a source plasma. The apparatus includes a process gas injection device constructed and arranged to inject a gaseous process material into a process region of the apparatus and a magnetic filter assembly constructed and arranged to impose a magnetic field generally between the source region and the process region to control the flow of charged particles from the source plasma into the gaseous process material to generate a process plasma in the process region. A source electrode is in contact with the source plasma and is constructed and arranged to control the potential of the source plasma. The apparatus includes support structure to support a workpiece so that the charged particles strike the workpiece.

An example method for processing a workpiece includes generating a source plasma, providing a process gas, controlling a flow of charged particles from the source plasma into the process gas to generate a process plasma from the process gas and to control properties of the process plasma, and striking the workpiece with charged particles from the process plasma.

### BRIEF DESCRIPTION OF THE DRAWINGS

FIG. 1 shows a schematic view of an illustrative embodiment of a plasma processing system constructed according to the principles of the present invention;

FIG. 2 shows a schematic cross-sectional view of an illustrated embodiment of a plasma processing apparatus in isolation constructed according to the principles of the present invention;

FIG. 3 is a schematic drawing showing a plan view of a plasma potential control electrode of the apparatus of FIG. 2 in isolation;

FIG. 4 is a schematic drawing showing a cross-section of the electrode taken along the line 4-4 of FIG. 3;

FIG. 5 is a schematic drawing showing a plan view of a magnetic filter assembly of the apparatus of FIG. 2 in isolation;

FIG. 6 is schematic drawing showing an elevational view of the magnetic filter assembly;

FIG. 7 is a schematic drawing showing an enlarged view of the portion of the magnetic filter assembly enclosed within the circle formed by the broken line in FIG. 6;

FIG. 8 is a schematic drawing showing a bottom plan view of a process gas injection device of the apparatus of FIG. 2 in isolation;

FIG. 9 is a schematic drawing showing a cross-section of the process gas injection device taken along the line 9-9 of FIG. 8;

FIG. 10 is a schematic drawing showing a spaced arrangement of a plurality of current conductive members and indicating the direction of current flow in each member;

FIG. 11 is a schematic drawing similar to the FIG. 10 except showing an additional row of current conductive members and indicating the direction of current flow in each member;

FIG. 12 is a schematic drawing showing a spaced arrangement of a plurality of permanent magnets and indicating the direction of magnetic polarity of each permanent magnet;

FIG. 13 is a schematic drawing similar to FIG. 1 except showing another combination of current flows in the members;

FIG. 14 is a schematic drawing similar to FIG. 12 except showing another arrangement of polarities;

FIG. 15 shows another example of a magnetic filter assembly;

FIG. 16 shows another example of a magnetic filter assembly; and

FIG. 17 shows an example of a magnetic filter assembly constructed by interengaging the magnetic filter assemblies of FIGS. 15 and 16.

### DETAILED DESCRIPTION OF THE EMBODIMENTS

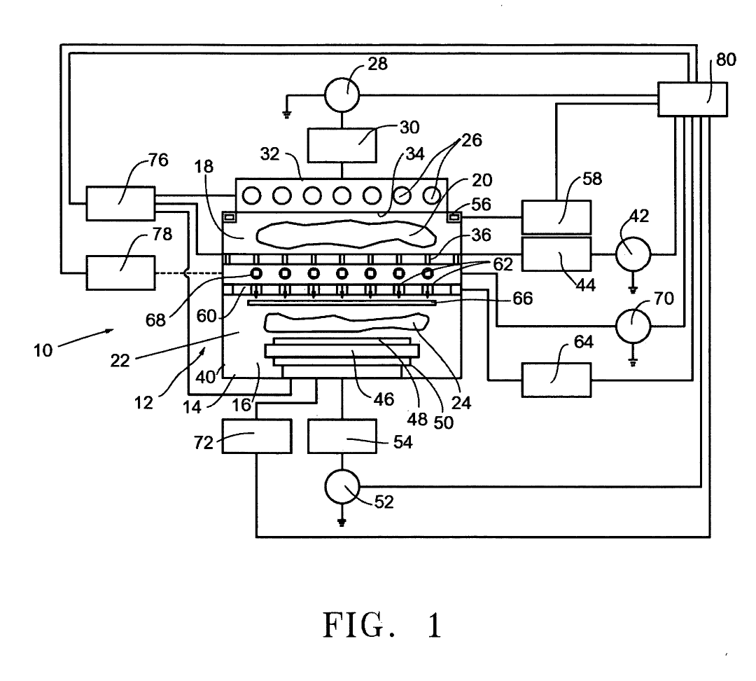

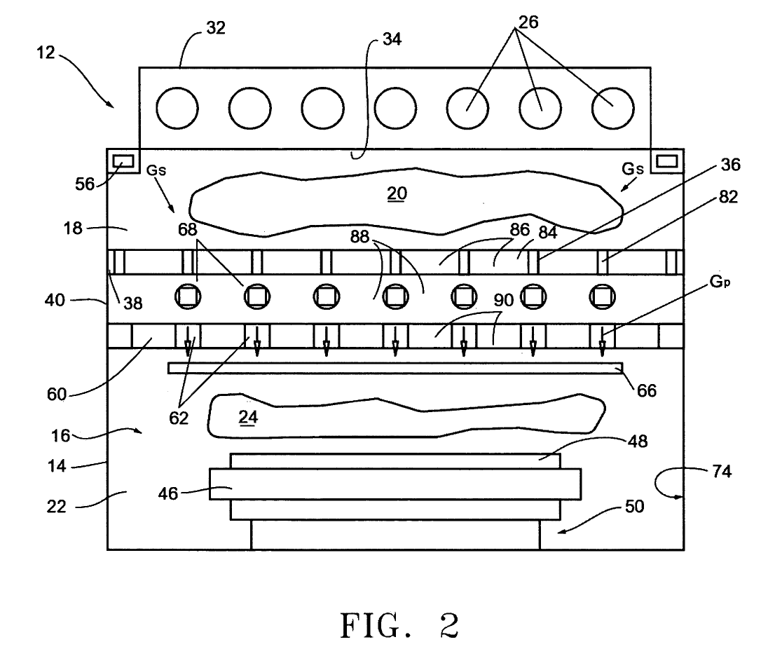

FIG. 1 shows a schematic representation of an example of a plasma processing system 10 that includes a plasma processing apparatus 12 constructed according to the principles of the present invention. The plasma processing apparatus 12 is shown schematically in isolated view in FIG. 2. The plasma processing apparatus 12 includes a reaction chamber 14 having an interior area 16. The interior area 16 includes a source region 18 for containing and supporting a source plasma 20 (see FIG. 2) and a process region 22 for containing and supporting a process plasma 24.

A plasma generating device in the form of a spiral- or coil-shaped radio frequency (RF) antenna 26 is mounted on the reaction chamber 14. In the illustrative embodiment of FIGS. 1 and 2 is a transformer coupled plasma (TCP) chamber and the antenna 26 is in the form of a spiral antenna or spiral member 26. The spiral member 26 is constructed and arranged to transmit energy to a gaseous source material in the source region 18 to generate the source plasma 20. The spiral member 26 may be operated to generate an inductively coupled plasma (ICP) in the source region 18. The spiral member 26 may be in electrical communication with a power source 28 through a matching network 30. The power source 28 is capable of transmitting an RF power signal. The matching network 30 may be inserted between the RF power source 28 and the spiral member 26 in order to maximize the power transferred from the power source 28 to the spiral member 26 and thereby maximize the power transferred from the spiral member 26 to a source plasma 20.

The spiral member 26 may be covered by a shielding structure 32 mounted on the reaction chamber 14. The shielding structure 32 may be constructed of a material appropriate to provide shielding of the energized spiral member 26 (such as a conductive material, for example). The shielding structure 32 may also improve the efficiency of power transfer from the power source 28 to the spiral member 26. The spiral member 26 may also be mounted on a support structure 34 which may be constructed of a dielectric material to facilitate transmission of the RF power generated by the energized spiral member 26 to the source region 20 of the reaction chamber 14. More specifically, the top wall of the reaction chamber 14 includes an opening which is covered by a dielectric material comprising the support structure 34. The support structure 34 seals the opening to allow a vacuum to be created in the interior area 16 of the reaction chamber 14, but allows the RF power to enter the interior area 16. The energized spiral member 26 may be operated to transmit energy to a gaseous source material in the source region 18 to produce an inductively coupled source plasma 20 having a relatively high uniform density.

The reaction chamber 14 includes an outer wall 40 which may be constructed of an appropriate metal material, such as aluminum. The reaction chamber 14 includes one or more outer side wall portions that at least partially surround the source region 18 and the process region 22. The wall 40 may be in electrical communication with a ground potential during plasma processing.

A source electrode in the form of a plasma potential controlling electrode 36 is mounted within the reaction chamber 14 to control the potential of the source plasma 20. The potential controlling electrode 36 is mounted on an isolator support 38 which is a non-electrically conductive structure that electrically isolates the electrode 36 from the wall 40 of the reaction chamber 14. The electrode 36 is in electrical communication with an RF power source 42 through a matching network 44. The matching network 44 may be inserted between the RF power source 42 and the electrode 36 in order to maximize the power transferred to a source plasma 20 by the plasma potential controlling electrode 36. The electrode 36 includes at least one surface that is substantially in contact with the source plasma 20.

An electrode assembly in the form of a chuck electrode 46 is mounted on a side of the chamber 14 opposite the side of the chamber 14 on which the spiral member 26 is mounted. The chuck electrode 46 provides support structure within the chamber that functions to support a workpiece 48 (which may be a semiconductor wafer, for example). The chuck electrode 46 may also be energized to generate a potential that attracts charged particles from the process plasma 24 towards the workpiece 48 so that the charged particles strike the workpiece 48 to etch material from the workpiece 48 or to sputter material on the workpiece 48. The example chuck electrode 46 is movably mounted in the reaction chamber 14 for movement generally toward and away from the process region 22 to adjust the distance between a process plasma supported in the process region of the chamber 14 and the workpiece 48. More specifically, the chuck electrode 46 is supported by a mechanical assembly (not shown) that is sealed within a flexible bellows structure 50 so that the chuck electrode 46 and the workpiece 48 are axially movable prior to or during a plasma processing operation. The chuck electrode 46 may be in electrical communication with a power source 52 through a matching network 54 to maximize power transfer.

The example chuck electrode 46 is an electrode that is in electrical communication with an RF power source 52. The chuck electrode 46 may have a ground voltage or an RF bias during a plasma processing operation. The electrical path to the chuck electrode 46 may further comprise an impedance match network 54 which may be used to optimize power transfer through the chuck electrode 46. The electrical bias of a chuck electrode is well known to those of skill in the art.

The apparatus 12 includes a source gas injection device 56 and a process gas injection device 60. The source gas injection device 56 is coupled to a source gas supply system 58 which operates to supply the one or more gases injected into the source region 18. The source gas injection device 56 is mounted in the reaction chamber 14 in the vicinity of the spiral member 26 and is operable to inject a source gas (or gasses) into the source region 18. An example of the source gas injection device 56 is a substantially annular structure. The source gas injection device 56 may be mounted generally about the periphery (i.e., 360°) of the spiral member 26 and may operate to inject (about the 360 degree periphery of the spiral member 26) and distribute one or more source gases toward the center of the source region 18 as indicated by the directional arrows Gs in FIG. 2. The source gas material may include, for example, a carrier gas (such as argon) and/or an etch gas.

The process gas injection device 60 includes an array of tubes 62 which, for example, may be equally spaced from one another and mounted across the reaction chamber 14 as shown, for example, in FIG. 2. The plurality of tubes 62 are coupled to a process gas supply system 64. The supply system 64 may supply one or more process gases for injection into the process region of the reaction chamber 14. Each gas injection tube 62 includes one or more gas outlet openings (not shown) which are oriented to direct the gaseous processing material into the process region 22 of the reaction chamber 14 as indicated by directional arrows Gp in FIG. 2. The array of tubes 62 may provide a symmetric array or other symmetric or asymmetric arrangement of gas outlet openings in the example reaction chamber 14 which distribute the process gas or gases in the process region 22. A cover structure 66, which may be constructed of silicon, may be mounted adjacent the array of tubes 62 and between the tubes 62 and the chuck electrode 46 to protect the gas distribution tubes from plasma bombardment.

A selected gas (or gasses) may be supplied to the source gas injection device 56 and/or the process gas injection device 60 to purge the chamber 14, for example, or to serve as a source gas or process gas, respectively, for plasma formation in the chamber interior 16. The plasma processing apparatus 12 includes a vacuum system 72 coupled to the plasma chamber 14 through a vacuum line. The vacuum system 72 may be coupled to the reaction chamber 14 through a gas outlet opening 74 as shown in the schematic view of FIG. 2 for removal of gases from the interior area 16 of the reaction chamber 14.

A magnetic filter assembly 68 is mounted within the reaction chamber 14 generally between the plasma potential controlling electrode 36 and the process gas injection device 60. As considered in detail below, the magnetic filter assembly 68 imposes a magnetic field generally between the source region 18 and the process region 22 to control the flow of charged particles from a source plasma 20 in the source region 18 into the process gas to generate a process plasma 24 in the process region 22. The magnetic field assembly 68 may include permanent magnets, electromagnets or a combination of both. The magnetic filter assembly is considered in detail below. The magnetic filter assembly 68 is in electrical communication with a power source 70 which may provide the magnetic filter assembly 68 with either a DC current or an RF current.

The spiral member 26 and the electrodes 36, 46 may be independently cooled by a fluid that circulates from a cooling system 76, through one or more fluid chambers (not shown) associated with the spiral member 26 and/or with each electrode 36, 46, and then back to the cooling system 76.

The plasma processing apparatus 12 may optionally include a plurality of voltage probes (not shown) in the form of a plurality of electrodes. Each electrode may be capacitively coupled to a respective transmission line between an RF power source 28, 42, 52, or 70 and the associated device 26, 36, 46, or 68. An example voltage probe is described in detail in commonly assigned pending U.S. patent application 60/259,862 (filed on Jan. 8, 2001), which application is incorporated in its entirety herein by reference. The plasma processing apparatus 12 may optionally include an optical probe 78 for determining plasma characteristics and conditions based on spectral and/or optical properties of the plasma.

The example apparatus 12 also includes a control system 80 which is electrically communicated to various components of the apparatus 12 to monitor and/or control the same. The control system 80 is in electrical communication with and may be programmed to control the operation of the gas supply systems 58, 64, the vacuum system 72, the cooling system 76, the voltage probe (not shown), the optical probe 78, and each RF power source 28, 42, 52, 70. The matching networks 30, 44, 54 may optionally be coupled to and controlled by the control system 80. Moreover, the electro-mechanically operated translation stage 50 for chuck electrode 46 can be operated and controlled via commands from control system 80.

The control system 80 may send control signals to and receive input signals (feedback signals, for example) from the system components 58, 64, 72, 76, 78, 28, 42, 52, 70, 30, 44, 54, 50 and the voltage probes. The control system 80 may monitor and control the plasma processing of a workpiece. As will become apparent, in an instance in which the magnetic filter assembly 68 includes one or more electromagnets, the control system 80 may be programmed to control the power source powering each electromagnet and thereby control the passage of or the “filtering” of charged particles, particularly electrons, from the source plasma into the process region. It can be understood that although FIG. 1 shows a single power source 70 in electrical communication with the magnetic filter assembly 68, in the instance in which the magnetic filter assembly 68 includes more than one electromagnet, the apparatus 12 may include an equal number of power sources so that, in some embodiments, each electromagnet of the magnetic filter assembly may be in electrical communication with a respective independently controllable power source.

The control system 80 may be provided by a computer system that includes a processor, computer memory accessible by the processor (where the memory is suitable for storing instructions and data and may include, for example, primary memory such as random access memory and secondary memory such as a disk drive) and data input and output capability for communication of data to and from the processor.

The methods of the present invention can be illustrated with reference to the example plasma processing system 10. The operation of the plasma processing system 10 can be understood with reference to FIG. 1. A workpiece (or substrate) 48 to be processed is placed on a support surface provided by the chuck electrode 46. The control system 80 activates the vacuum system 72 which initially lowers the pressure in the interior area 16 of the plasma chamber 14 to a base pressure (typically 10⁻⁷ to 10⁻⁴ Torr) to assure vacuum integrity and cleanliness of the chamber 14. The control system 80 then raises the chamber pressure to a level suitable for forming a source plasma and for processing the workpiece 48 with the plasma (a suitable interior pressure may be, for example, in the range of from about 1 mTorr to about 1000 mTorr). In order to establish a suitable pressure in the chamber interior 16, the control system 80 activates the gas supply system 58 and/or the process gas source system 64 to supply a source gas and/or a process gas through the gas injection devices 56, 60, respectively, to the chamber interior 16 at a prescribed flow rate (or rates) and the vacuum system 72 may be throttled, if necessary, using a gate valve (not shown).

The control system 80 then activates the RF power sources 28, 42, 52, 70 to power the spiral member 26, the plasma voltage controlling electrode 36, the chuck electrode 46 and the magnetic filter assembly 68. The RF power sources 28, 42, 52, 70 may provide voltages to the spiral member 26, the electrode 36, the chuck electrode 46, and the magnetic filter assembly 68 at selected frequencies (including a zero frequency in the instance in which a ground or other constant voltage is applied). The control system 80 may, during a plasma processing operation, independently control the RF power sources 28, 42, 52, 70 to adjust, for example, the frequency and/or amplitude of the voltage transmitted by each power source.

The RF power source 28 may be operated to energize the spiral member 26 to convert the source gas to a source plasma. The ICP in the source region 18 has a short, flat volume and a relatively high density. The plasma density of the source plasma may be, for example, in the range of from about 1×10¹² cm⁻³ to about 5×10¹² cm⁻³. A typical electron temperature is, for example, several electron volts and a typical operating pressure is, for example, in the 10's of mTorr range. The plasma potential of the source plasma will be, for example, in the 10's of volts range. The operator or the controller 80 can control the potential of the source plasma by controlling the DC or RF bias voltage applied to the potential controlling electrode 36. When a plurality of electrodes are in contact with the plasma, each electrode of the plurality having a comparable amount of surface area in contact with the plasma, the source plasma takes on the potential of the most positive electrode. In the instance in which the potential controlling electrode 36 is grounded, the source plasma may only assume a potential slightly higher than ground potential. In the steady state, the total electron current leaving the source plasma may be balanced by the total ion current to the system wall 40. When the potential controlling electrode 36 is biased to a voltage significantly above ground potential, the electron current attracted to the potential controlling electrode 36 increases. When this occurs, the total electronic current lost from the source plasma may exceed the total ion current, and the plasma potential may be forced to increase until a new steady state is reached at which the electron and ion currents are about equal to one another. In this way, a DC bias on the potential controlling electrode 36 can control the plasma potential of the source plasma. If the ground surface area is large, increasing ion current to the grounded surface may not only increase the ion energy loss, but it may also increase the ion sputtering from the grounded surface. Therefore, RF bias instead of DC bias may be used for controlling the potential of the source plasma. It has been commonly known by those skilled in the art of RF plasmas that a RF bias may cause a self-generated DC bias on the electrode that is positive with respect to the ground potential if the ground surface area is comparable to the surface area of the electrode without causing additional sputtering.

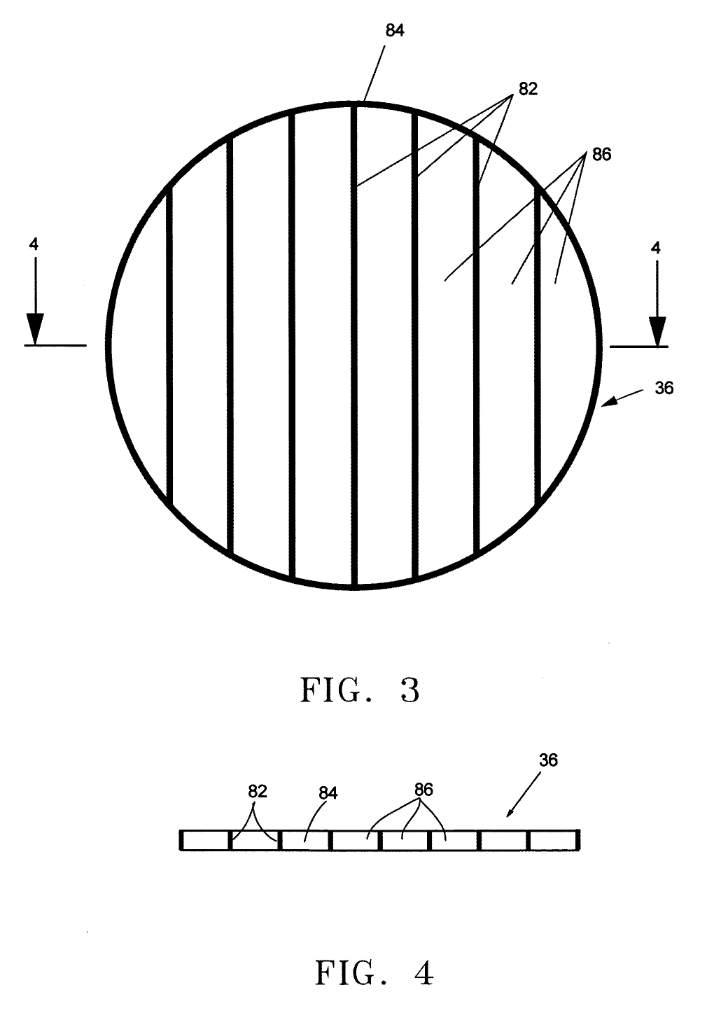

The construction of the example potential controlling electrode 36 can be understood from the FIGS. 3 and 4. The plasma potential controlling electrode 36 is comprised of a plurality of elongated structures 82 which are secured within an annular frame 84. The elongated structures 82 are essentially parallel to one another and are spaced apart to provide a series of slot-like openings of various sizes and shapes, generally designated 86. The elongated structures 82 and the frame 84 are each constructed of an electrically conductive material and may be constructed of aluminum, for example, or other suitable metal material. The openings 86 are large enough to provide a high degree of plasma flow transparency from the source region 18 to the process region 22. The total surface area of the electrode 36 is large enough so that at least a portion of the source plasma 20 is in substantial contact with the electrode 36 during processing. The source plasma 20 assumes the potential of the surface having the highest potential that is substantially in contact with the source plasma 20. The electrode 36 is constructed so that it provides a surface or surfaces that are in substantial contact with source plasma 20. The surface area of the potential controlling electrode 36 that is in contact with the source plasma 20 is large relative to the surface area of the remaining surfaces (including walls 40, for example) surrounding the source plasma 20. In this way, the voltage of source plasma 20 can be controlled by controlling the voltage of the electrode 36.

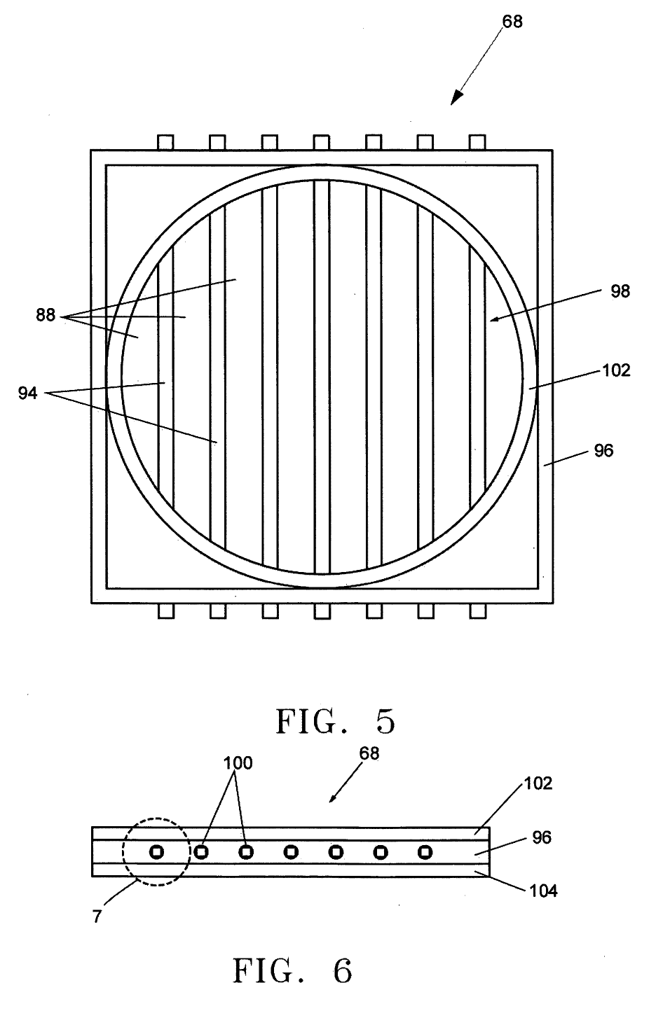

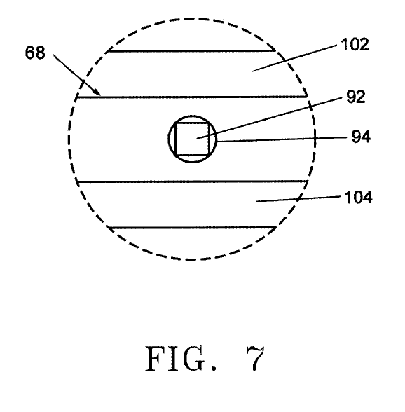

The source plasma 20 diffuses through the openings 86 in the electrode 36, through slots or openings 88 in the magnetic filter assembly 68, through slots or openings 90 in the process gas injection device 60 and into the process region 22 and forms a process plasma 24 there. The structure of the magnetic filter assembly 68 can be understood from FIGS. 5-7.

The magnetic filter assembly 68 is an illustrative embodiment comprised of a plurality of bar-type permanent magnets 92, each of which is mounted within a tubular housing 94. Each bar magnet 92 extends the length of the associated tubular housing 94 so that each magnet 92 extends between the side walls 40 of the chamber when the magnetic filter assembly 68 is mounted in the apparatus 12. Each housing 94 may be constructed of an electrically conductive material such as an appropriate metal material or, alternatively, each housing 94 may be constructed of a dielectric material, as another alternative, each housing 94 may be made of both a metal material and a dielectric material. The example housings 94 are constructed of aluminum. The assembly 68 further includes a frame 96 having a central opening 98. Each housing 94 is secured within a pair of openings 100 on opposite sides of the frame 96. A pair of annular wall structures 102, 104 are mounted about the opening 98 on respective opposite sides thereof. The annular wall structures 102, 104 may form part of the wall 40 of the reaction chamber 14 when the frame 96 is mounted in the apparatus 12. The housings 94 of the magnetic filter assembly 68 may be either in electrical communication with a ground potential or in electrical communication with a floating (for example, RF) potential. As mentioned, the housings 94 are spaced to define a plurality of openings 88 therebetween.

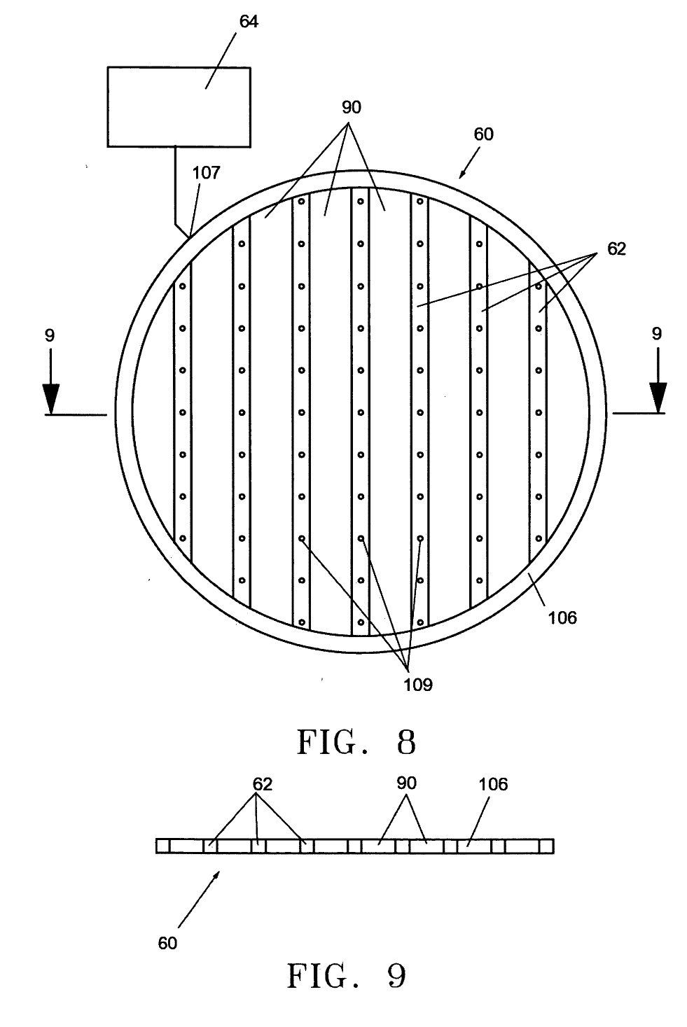

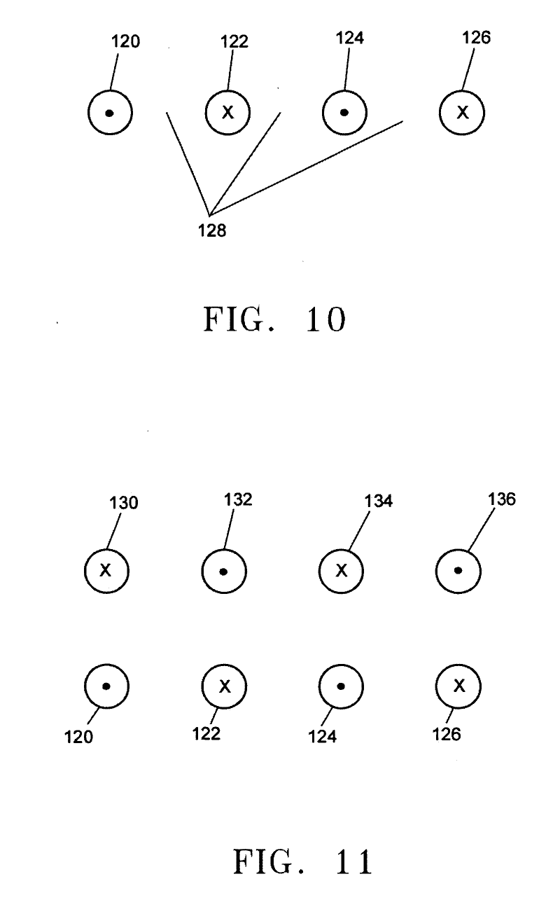

The details of the construction of the process gas injection device 60 can be understood from FIGS. 8 and 9. Each tube 62 of the process gas injection mechanism 60 may have a generally rectangular transverse cross-section and may be constructed of an appropriate metal material such as aluminum. The tubes 62 are secured within an annular tubular frame 106 which may be constructed of an appropriate metal material such as aluminum. The tubes 62 may be secured to the frame 106 by welding or other appropriate method such that gas that is introduced into the frame 106 flows into and through the tubes 62. The process gas supply system 64 (shown schematically in FIG. 8) may be coupled to device 60 through a gas inlet 107 in the frame 106. The tubes 62 have a series of gas outlets 109 through which the gas flows into the apparatus. As mentioned, the tubes 62 are spaced to provide a series of openings 90 therebetween. The process gas injection device 60 may optionally be in electrical communication with a grounded potential or to a floating potential.

As best seen in FIG. 2, the openings 86, 88, 90 in the electrode 36, the filter assembly 68, and the process gas injection device 60, respectively, are aligned with one another (vertically aligned in the example apparatus 12) and each series of vertically aligned openings 86, 88, 90 in the components 36, 68, 60 are of approximately equal dimensions to one another to facilitate passage of charged particles from the source region 18 to the process region 22.

Electrons and charged particles (example, positive ions) from the source plasma in the source region diffuse through the openings 86, 88, 90 into the process region 22 and form a process plasma 24 there. The magnetic filter assembly 68 imposes a magnetic field between the source region 18 and the process region 22 which tends to filter out the high energy electrons and prevent them from diffusing into the process plasma 24. Energetic electrons whose mean free path of collision is longer than the magnetic field scaling (that is, the size of the magnetic field region) are reflected by the magnetic field across the openings 90 in the magnetic filter assembly 68 and are thereby prevented from entering the process plasma 24. Therefore, the electrons in the process plasma 24 have a lower average energy (that is, a lower electron temperature) than the electrons in the source plasma 20. A typical electron temperature of a process plasma 24 is one electron volt or less, depending on the magnitude of the magnetic fields imposed by the magnetic filter assembly 68. Generally, the stronger the magnetic field imposed by the magnetic field assembly 68, the lower the electron temperature and the lower the electron density of the process plasma 24.

The ions moving from the source plasma 20 to the process plasma 24 will be accelerated (downward in the example apparatus 12) with an energy approximately equal to the difference between the source plasma potential (V_{SP}) and the process plasma potential (V_{PP}) times the ionic charge. The ion energy can be expressed by the following formula:

Eⁱ=q(V_{SP}−V_{PP}), (Equation 1)

where Eᵢ is the ion energy, q is the charge on the ion, V_{SP} is the plasma potential of the source plasma 20 and V_{PP} is the plasma potential of the process plasma 24. In the instance in which the potential of the process plasma 24 is maintained at ground potential, the ion energy is determined by the bias voltage applied to the potential controlling electrode 36. This relation to can be expressed mathematically as shown in Equation 2:

Eᵢ≈q(V_{SP}). (Equation 2)

When the housings 94 of the magnetic filter assembly 68 have a ground potential, the ions coming from the source plasma 20 will be directed toward the process plasma 24 with an energy comparable to the difference between the potential of the source plasma 20 and the potential of the process plasma 24 times the ionic charge (as given by Equation 2). The ions entering the process plasma 24 may thus attain an energy that is directed toward the workpiece 48 before they enter the process plasma sheath. Etching is more effective when carried out with ions having an energy directed toward the workpiece 48. When the direct energy of the ions is high enough, a high etch rate can be achieved while the workpiece 48 (e.g., a semiconductor wafer) is grounded.

It can thus be understood that the magnetic field imposed by the magnetic filter assembly 68 can function to separate the plasma volume within the interior area 16 of the reaction chamber 14 into two plasmas 20, 24 occupying two regions: the high density source plasma 20 in the source region 18 in which the primary electrons are highly effectively confined and the relatively cool process plasma 24 in the process region 22 having very few or no ionizing electrons.

In DC plasma and in RF plasmas, the primary electrons that are accelerated directly by the external electric field are responsible for production of the process plasma 24 and for the shape of the electron energy distribution function (EEDF) of the process plasma 24. The primary electrons with energy of between twenty and one hundred electron volts (20 to 100 eV's) generally have a mean free-path of ionization collisions that is much longer than any of the dimensions of the source region 18 of the reaction chamber 14 containing the source plasma 20. Confining the primary electrons to the source plasma 20 in the source region 18 increases the density of the process plasma 24, which in turn increases the production efficiency of the system 10, and also improves the uniformity of the process plasma 24 and of the processed workpiece 48.

The EEDF of a process plasma 24 can be controlled by controlling the strength of the magnetic field imposed by the magnetic filter assembly 68. The magnetic field of the magnetic filter assembly 68 can be controlled by providing individual magnets in the array of different strengths, by controlling the spacing and number of magnets, and so on. The controlling of the strength of the magnetic field controls the dissociation of the process gases because the dissociation process which occurs in the process plasma 24 will depend to a large extent on the electron energy in the process plasma. Because the imposed magnetic field functions to reflect high energy electrons and thereby confine them to the source region 18, the process plasma has a relatively low electron temperature. Therefore, adjustment of the magnetic field strength of the magnetic field imposed by magnetic filter assembly 68 can lead to control of the plasma chemistry of process plasma 24.

It has been found experimentally that a magnetic field having a magnetic flux of 200-300 G-cm is strong enough to separate a highly ionized source plasma 20 having an electron temperature of from approximately 4 to approximately 5 eV from a relatively cool process plasma 24 having an electron temperature of less than 1 eV. Control of the electron energy of the process plasma 24 in the range of from approximately 1 to approximately 3 eV can be achieved by varying the magnetic flux imposed by the magnetic filter assembly 68 in the range of from 100 to 200 G-cm. Examples of magnetic filter assemblies that include electromagnets which provide variable magnetic fields which covers these example limits and a wider range of limits are described below.

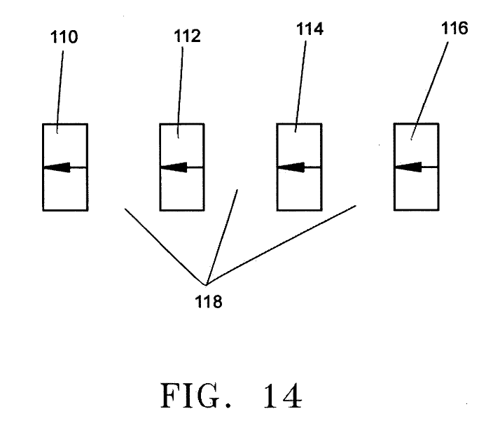

Many different embodiments of the magnetic filter assembly are contemplated and within the scope of the invention. For example, the magnetic filter assembly could include an array of permanent magnets 92 as shown in FIGS. 5-7. When an array of permanent magnets 92 (represented schematically by rectangles in FIGS. 12 and 14) are used to create the imposed magnetic field, the poles of the magnets can be arranged in several different ways. For example, the array of magnets 92 could be arranged so that all of the north poles “face” in the same transverse direction. In the illustrative embodiment of FIGS. 5-7, for example, the permanent magnets 92 that extend the lengths of the associated tubular housings 94 could be arrangement such that the north poles thereof face in the same direction. This type of arrangement can be understood from the schematic diagram of FIG. 14. FIG. 14 shows four magnets 110, 112, 114, 116 and the spaces 118 therebetween. The magnets are arranged so that the north pole of each magnet is directed toward the one side of the chamber and the south pole of each magnet is directed toward the opposite side of the chamber. Another example arrangement that can be used when the magnetic filter assembly is comprised of a series of parallel bar-type magnets is shown schematically in FIG. 12. In this example, the magnets 110, 112, 114, 116 are arranged such that the north pole of every other magnet (110 and 114, for example) faces in one direction and such that the north pole of each magnet therebetween (112 and 116, in this example) faces in the opposite direction. When greater (or lesser) numbers of permanent bar magnets are used to construct the magnetic fields assembly, these patterns are simply repeated. It can be understood that these arrangements of the poles are examples only and that many other possible combinations are possible.

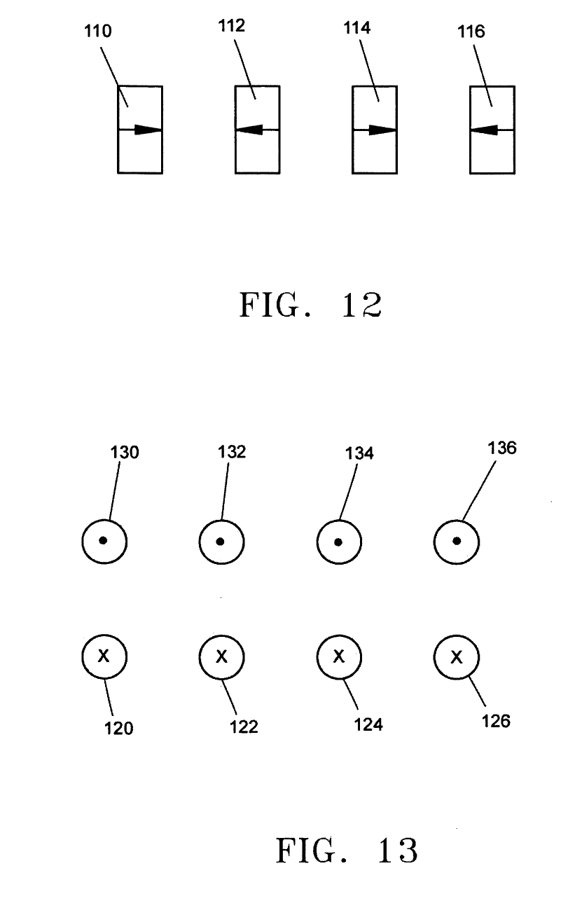

The magnetic fields of a magnetic filter assembly can also be provided by electromagnets. For example, a magnetic filter assembly could be comprised of an array of current-carrying members that are generally parallel to one another, that are spaced apart from one another, and that extend generally transversely across the interior area 16 of the reaction chamber 14 in a manner similar to the arrangement and spacing of the permanent magnets shown in FIG. 2, for example. More specifically, in one embodiment of this type of magnetic filter assembly, one or more current carrying members could be mounted within and extend the length of a respective tubular housing 94 (in place of the permanent magnet therein) of the magnetic filter assembly of FIG. 5, for example. Each current carrying member may be in electrical communication with a source of current (not shown). FIG. 10 shows an example of an array of current-carrying members (which could be, for example, an array of rigid structures each of which is constructed of an electrically conductive material such as a suitable metal material and each of which could be in electrical communication with a respective controllable current source) which could provide the magnetic fields for a particular magnetic filter assembly.

Specifically, FIG. 10 shows four example current-carrying members 120, 122, 124, 126 and the spaces 128 therebetween. Charged particles moving from a source plasma into a process plasma would pass through the spaces 128. Each elongated current-carrying member is shown schematically in end view as a circle. The circles having “dotted” centers (members 120, 124) represent current-carrying members in which the current is flowing toward the viewer (that is, “out of” the page). The circles having an “X” in the center (members 122, 126) represent current-carrying members in which the current is flowing away from the viewer (that is, “into” the page). The arrangement of current-carrying members and the distribution of currents flowing therein in FIG. 10 is generally referred to as a “single picket fence”. A single picket fence creates a current grid that extends across the chamber. Each member 120, 122, 124, 126 may comprise a separate DC electromagnet.

FIG. 11 shows another example arrangement of current-carrying members. This arrangement includes a second layer of current-carrying members 130, 132, 134, 136. In this arrangement, each current carrying member 130, 132, 134, 136 may be enclosed within a tubular housing in a manner similar to the manner in which the permanent magnet 92 is mounted in the housing 94 of FIG. 5, for example. That is, a current carrying member may extend through the associated housing 94 (in place of the permanent magnet 92) and be in electrical communication with a controllable source of current. The current-carrying members 130, 132, 134, 136 are generally parallel to one another and are generally parallel to and vertically spaced from the first layer of current-carrying members 120, 122, 124, 126. The arrangement of FIG. 11 is generally referred to as a “double picket fence”. The double picket fence uses two current layers (current-carrying members 120, 122, 124, 126 providing the first layer and current-carrying members 130, 132, 134, 136, providing the second layer) to impose a filtering magnetic field between the source region and the process region.

Many current flow patterns can be achieved with this double picket fence structure. In the example shown in FIG. 11, the directions in which the current is flowing in each current-carrying member is indicated with dots and X's in the manner described above. The current patterns shown in FIG. 11 create a magnetic field similar to the one created by the array of permanent magnets in FIG. 12.

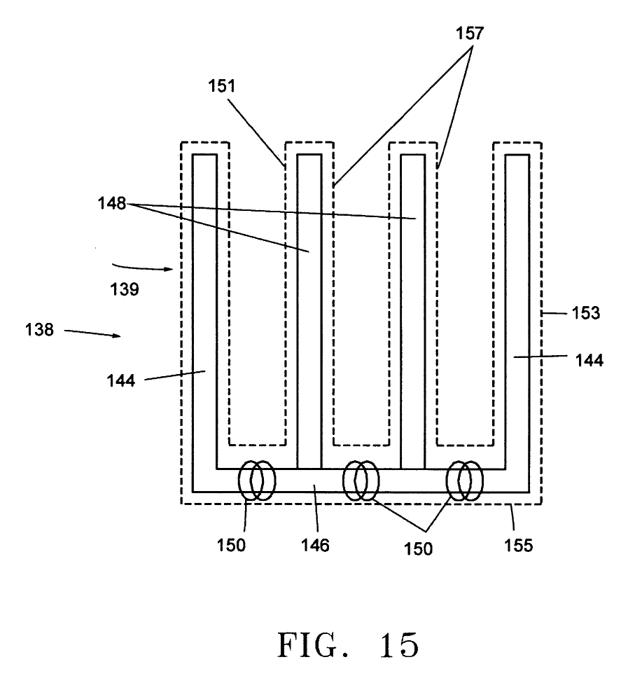

FIG. 13 shows an arrangement of current-carrying members identical to that shown in FIG. 11. The current flows that are illustrated in FIG. 13 create, in effect, two current “sheathes”, the flow of current in one sheath (comprised of current-carrying members 120, 122, 124, 126) going in one direction, and the current in the other sheath (comprised of current-carrying members 130, 132, 134, 136) going in the opposite direction. This arrangement of current-carrying members and current flow distributions creates a field generally referred to as a “magnetic wall”. In a magnetic wall, the magnetic field is going in one direction. The arrangement of current-carrying members and the currents flowing therein shown in FIG. 13 create a magnetic field similar to the magnetic field created by the array of permanent magnets shown in FIG. 14.

Each example arrangement of FIGS. 10-14 produces a different magnetic field. One advantage of using currents to create magnetic fields (as in FIGS. 10, 11 and 13) is that the magnetic field strength can be varied. The magnitude of the currents required to create magnetic fields of sufficient strength to filter electrons effectively in the reaction chamber 14 can be quite high, however, and may be a few hundred amperes, for example. Arrangements such as those shown in FIGS. 12 and 14 are advantageous because they do not require an external power supply, but the magnetic fields created by a fixed array of permanent magnets cannot be varied.

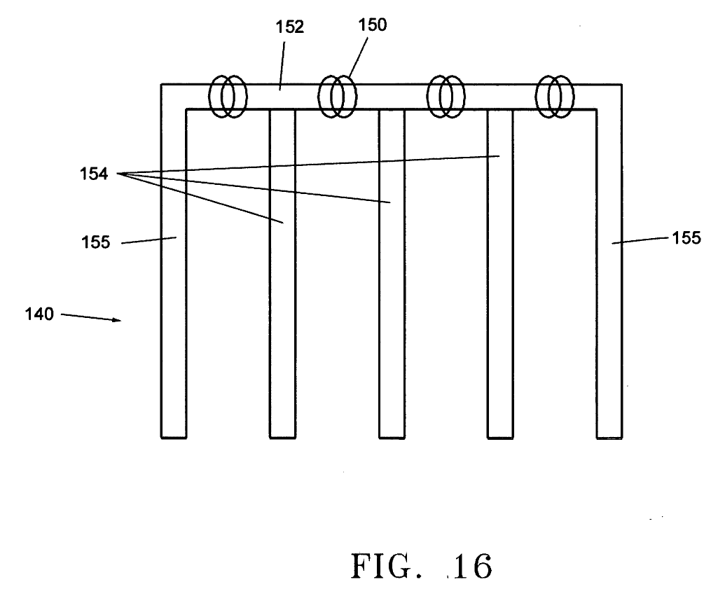

FIGS. 15-17 show examples of three magnetic field assemblies 138, 140, 142 which provide variable magnetic fields without requiring high currents. FIG. 15 shows a U-shaped member 139 having legs 144 which extend from a bight portion 146. The U-shaped member 139 comprises a horseshoe-type electromagnet. An array of permanent magnets 148 are each connected to the bight portion 146 of the U-shaped member 139 and extend outwardly therefrom in spaced relation to the leg portions 144. The U-shaped member 139 can be energized to create an electromagnet. The U-shaped member may, for example, be an integral structure that is constructed of a magnetic flux-conducting material (such as iron or other suitable metal material) that is shaped to define the bight and leg portions 146, 144. One or more coil magnets 150 are wound around the bight portion 146 of the U-shaped member 139. Each coil magnet 150 may be in electrical communication with a respective controllable current source (not shown). When each coil magnet 150 is energized, magnetic field energy generated by the coil magnets 150 is conducted through the U-shaped member 139. The U-shaped member 139 may comprise a horseshoe-type magnet. The permanent magnets 148 improve the properties of the horseshoe magnet 139. More specifically, the permanent magnets 148 contribute some DC magnetic field to make the magnetic field generated by the U-shaped member 139 when the coil magnets 150 are energized to increase the total field strength generated by the assembly 138. The permanent magnets 148 also tend to concentrate the magnetic flux produced by the U-shaped member 139/coil magnets 150 in the center region 151 of the magnetic field assembly 138.

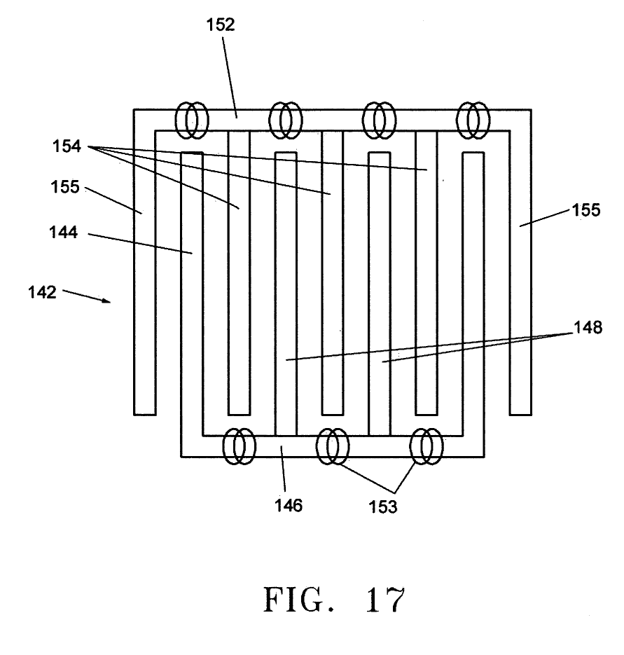

The magnetic filter assembly 140 shown in FIG. 16 is similar in construction to the magnetic filter assembly 138 of FIG. 15, except that the bight portion 152 of the assembly 140 is longer than the bight portion 146 of assembly 138 and the magnetic filter assembly 140 includes three permanent magnets 154 connected to the byte portion 152 thereof. A plurality of conductive coils 153 are wound around the bight portion 146 of the assembly 140.

Each magnetic filter assembly 138 and 140 may be contained within a housing. FIG. 15 shows an example of a housing 153 (in dashed lines) around the magnetic filter assembly 138. The housing 153 may be constructed of a metal material such as aluminum or other appropriate material. The housing 153 includes a tubular body portion 155 and a plurality of tubular arms 157 which extend outwardly from the body portion 155 and surround and enclose the leg portions 144 and the permanent magnets 148 of the magnetic filter assembly 138. A similar housing (not shown) may be provided for the magnetic filter assembly 140.

The magnetic filter assemblies 138, 140 are constructed to fit together as shown in FIG. 17 to create magnetic filter assembly 142. When the magnetic filter assemblies 138, 140 are interengaged with one another to form assembly 142, the magnetic field created by the assembly 142 depends on how the component assemblies 138, 140 are operated. For example, the assemblies 138, 140 which make up the assembly 142 could be operated so that the magnetic fields created by the assemblies 138, 140 coincide with one another and therefore reinforce one another. For example, it can be understood that the magnetic field assembly 140 in FIG. 17 could be energized (by energizing coils 153) such that the field created by the assembly 140 forms a north pole at the top of the page. The assembly 138 could impose a magnetic field (by energizing the coils 150) in which the north pole is at the top of the page or the bottom of the page, depending on the direction of the currents in the coils 150. Thus, it can be appreciated that component assemblies 138, 140 of magnetic filter assembly 142 could be arranged and operated such that the north poles of the two assemblies 138, 140 are on the same side of the assembly 142, or such that the north poles of the two component assemblies 138, 140 are on opposite sides of the assembly 142.

When the assembly 142 is operated such that the north poles of the two component assemblies 138, 140 are on the same side of the assembly 142 (that is, such that the north poles or magnetic fields of the two component assemblies 138, 140 are in the same direction or coincide with one another), this arrangement would yield a magnetic field between the layers of plasma similar to that shown in FIG. 14. Alternatively, when the assembly 142 is operated such that the north poles of the two component assemblies 138,140 are on opposite sides of the assembly 142 (or are anti-directional with one another, i.e. the fields are in opposing directions to one another), this arrangement would yield a magnetic field between the layers of plasma similar to that shown in FIG. 12.

In the instance in which the respective magnet fields of the two component magnetic assemblies 138, 140 of the assembly 142 are in the same direction, a magnet wall type of filter is formed. In the instance in which the respective magnet fields of the two component magnetic assemblies 138, 140 of the assembly 142 are anti-directional (that is, so that the respective fields of the assemblies 138, 140 are in opposing directions to one another), a magnetic cusp filter is created.

The mechanism by which the EEDF (electron energy distribution function) of the process plasma 24 is controlled is considered below. In this example, a magnetic cusp filter is used to control the EEDF. The leakage width for the collision-less fast electrons has been found to be approximately twice their gyroradius, 2 rₚ, where the gyroradius, rₚ, is given by the following relationship:

rₚ=(2eVp/m)^{1/2}/(eB/mc) (Equation 3)

where the primary electron energy is eVp, e is the fundamental charge, m is the electron mass, c is the speed of light in a vacuum and B is the magnetic field strength. The leakage width of the primary electrons is inversely proportional to the magnetic field strength B.

The leakage rate for the cooled plasma is dominated by the leakage of the ions. Electron leakage is strongly influenced by the ambipolar electric field. In general, the electrons that leak through the magnetic filter are the relatively slow electrons. These relatively slow electrons are further cooled by collisions with the neutral gas, as in the after-glow discharge.

The apparatuses and methods of the present invention have many advantages. It can be understood from an examination of FIG. 2, for example, that if the electrode 30, the magnetic filter assembly 68, the process gas injection device 60 and the supporting structures associated therewith were to be removed from the apparatus 12, the remaining portions of the apparatus 12 (that is, the reaction chamber 14, the chuck electrode 46, and the transformer coupled plasma source spiral member 26) comprise a conventional transformer coupled plasma (TCP) reactor. Conventional TCP reactors have advantages and disadvantages, however, when used for etching or deposition. TCP reactors can be operated to generate high density plasmas, for example, which generally provide a good etch rate, which is desirable, but plasmas generated by conventional TCP reactors have high electron temperatures (typically in the 3-4 eV range), and do not provide the ability to control the electron energy distribution function (EEDF) of the plasma. As a result, these reactors produce high dissociation rates. Generally, the dissociation of a plasma can be related to the density of the plasma, the residence time of a gas atom or molecule moving around in the plasma and to the EEDF of the plasma.

It can be appreciated that although the examples and illustrative embodiments herein use a TCP reactor, this is done to facilitate describing the invention and is not intended to limit the scope of the invention. Other methods and apparatuses may be used to generate the source plasma. For example, the source plasma 20 may in some embodiments of the invention be generated by inductive coupling or, as another alternative, by capacitive coupling.

High dissociation rates are disadvantageous in many plasma process operations. For example, high dissociation rates may be disadvantageous in instances in which the process plasma is used to etch silicon dioxide (which commonly occurs in commercial semiconductor fabrication). Fluorocarbon chemistry is often used to etch the oxide features in a silicon dioxide wafer. These oxide features may include, for example, semiconductor contacts or trenches. A typical combination of gases used to etch a silicon dioxide wafer utilizing a conventional TCP reactor may include a fluorocarbon gas (such as C₄F₈, for example), an oxygen containing gas (such as CO, CO₂, or O₂, for example), and a carrier gas (such as argon, for example). The argon functions to dilute the fluorocarbon-containing and oxygen-containing gases and may also be ionized and used to bombard the surface of the substrate to increase the energy of the etch chemistry.

Often during semiconductor fabrication, for example, the surface of the workpiece has areas of silicon dioxide, photoresist, silicon, silicon nitride and so on. In particular, layers of silicon or silicon nitride can be exposed upon etching through an oxide layer; and, due to process non-uniformities, an over-etch step may be required to complete etching through the oxide layer across the entire substrate. It is often desirable during a semiconductor processing operation to etch the silicon dioxide at a faster rate than the other materials. This requirement is referred to as a requirement for a high degree of etch selectivity for silicon dioxide. Typically, however, inductively coupled plasma sources in general, and TCP reactors in particular, are highly dissociative which leads to the production of relatively high amounts of fluorine radical. When too much fluorine radical is present in the process plasma, the fluorine radicals etch the silicon faster than they etch the silicon dioxide. Thus, a high degree of dissociation in the plasma leads to the formation of a high degree of fluorine radical which leads to a loss of etch selectivity and a consequent degradation in the quality of the semiconductor devices produced.

Several attempts have been made to reduce the amount of dissociation that occurs in conventional ICP reactors. For example, scavenger materials are sometimes placed in the plasma source. An example of a scavenger material would be silicon which is sometimes provided in the form of a plate. The silicon plate erodes during processing, thereby putting silicon into the plasma chemistry. The silicon reacts with some of the fluorine radical and thereby removes some fluorine radical from the plasma. It may also be desirable to “clad” the surfaces of the chamber with a material or materials suitable for carrying out a specific process. For example, during an oxide etching operation, such materials might include silicon, quartz, and so on. These materials may also be used for other reasons as well.

The apparatuses and methods of the present invention reduce unwanted dissociation and consequently reduce the amount of fluorine radical in the process plasma 24. This improves etch selectivity. Thus, the plasma potential controlling electrode 36, the magnetic filter assembly 68 and the process gas injection device 60 can be operated to improve the properties of the process plasma 24. The ability to control the magnetic field strength of the magnetic field assembly 68, for example, provides the operator with the ability to control the energy of the electrons diffusing into the process plasma 24. This provides the capability of controlling the EEDF of the process plasma 24. The potential controlling electrode 36 provides the ability to control the potential of the source plasma 20. By varying the DC or RF voltage of the potential controlling electrode 36, the ion energy of the ions moving from the source plasma 20 to the process plasma 24 can be controlled. By controlling the EEDF and the ion energy of the process plasma 24, the operator can reduce the amount of the dissociation that occurs while keeping the density of the process plasma 24 relatively high.

More specifically, it can be understood from FIG. 2, for example, that the electrode 36, the filter assembly 68 and the process gas injection device 60 essentially divide the interior area 16 of the reaction chamber 14 into the two regions 18, 22. To process a workpiece (such as a silicon dioxide wafer) utilizing the apparatus 12, argon or a similar source gas could be injected in the source region 18 to produce (using, for example, the energized spiral member 26) a relatively high density argon plasma. The argon plasma would include positively charged argon ions and relatively high energy electrons. The process gas may be introduced through the process gas injection device 60 into the process region 22 of the chamber 14. The process gas may include the fluorocarbon species and perhaps some argon and/or oxygen containing gases. In other words, the process gas injection device 60 introduces the gases that will ultimately be dissociated to produce the etch chemistry of the plasma that strikes the workpiece 48. The magnetic filter assembly 68 allows the relatively low energy electrons to enter the process region, but blocks the relatively high energy electrons from entering the process region, thereby confining them to the source region 18. The process gases or species in the process region 22 interact with these relatively low energy electrons in the process region 22, but these electrons are not highly dissociative. Thus, if C₄F₈ were introduced into the process region 22, the energy of the electrons that enter the process region 22 could be controlled to control the dissociation chemistry of the C₄F₈ to minimize the amount of fluorine radical produced in the process plasma 24.

The plasma potential controlling electrode 36 controls the potential of the source plasma 20 and cooperates with the magnetic filter assembly 68 to control the diffusion of the plasma from the source region 18 into the process region 22. The presence of a magnetic filter in the center of the chamber 14 inhibits the source plasma from diffusing into the process region 22. Generally, the imposed magnetic field controls the passage of electrons from the source plasma into the process plasma by inhibiting the passage of relatively high energy electrons from the source plasma into the process plasma but allowing the passage of relatively low energy electrons from the source plasma into the process plasma. And generally, the potential controlling electrode 36 helps control the passage of ions into the process plasma by controlling the potential of the source plasma. The plasma density of the source plasma will typically, for example, be much higher then the plasma density of the process plasma. The presence of the potential controlling electrode provides the source plasma with an essentially uniform potential and provides the operator with the ability to adjust the potential of the source plasma.

Because the ions are much more massive then the electrons, they are less affected by the magnetic fields imposed by the magnetic filter assembly. Consequently, if the potential of the source plasma were not controlled to control the movement of the ions from the source plasma into the process plasma, the process plasma could acquire undesirable properties or the plasma 20, 24 in the reaction chamber 14 could become unstable or turbulent. For example, if the potential of the source plasma 20 were not controlled, initially a relatively high number of positive ions from the source plasma could diffuse into the process plasma while some electrons are inhibited from passing into the process region by the magnetic field. As a result, the process plasma would tend to acquire a positive space charge. This would eventually tend to repel additional positive ions from migrating into the process plasma 24 which would limit plasma density of the process plasma 24. The density of the process plasma 24 can be increased by adjusting the magnetic field to allow migration of electrons from the source plasma 20 into the process plasma 24. If too many electrons are allowed to pass into the process plasma 24, however the process plasma 24 may develop a negative space charge. A negative space potential in the process plasma 24 may tend to attract positive ions from the source plasma 20 into the process plasma 24. If the potential of the source plasma 20 were not controlled, these processes (that is the migration of the positive ions and the migration of the negative electrons) could occur in an uncontrollable manner and this may result in turbulence or instability in the plasma 20, 24 in the chamber 14. The potential control electrode 36 allows the operator (or the controller) to adjust the potential of the source plasma 20 so that charged particles in plasma flow from the source region into the process region in a steady and controlled manner. By controlling the potential of the source plasma and the strength of the magnetic field, the conditions can be adjusted so that ions with high energy and a relatively large current of relatively cold electrons flow into from source plasma 20 into the process plasma 24. In general, ions coming to the process region with a controllable directed energy may enhance plasma flow to the wafer and therefore enhance processing efficiency.

It can be understood that the system 10 and the apparatus 12 (including the various components thereof shown in the FIGS. 3-17) are example embodiments that are intended to illustrate the principles of the invention, but which are not intended to limit the scope of the invention. Alternative arrangements and additional embodiments are contemplated and within the scope of the invention. For example, although the example apparatus 10 includes three separate components to control the potential of the source plasma, to impose the magnetic fields and to inject the process gas (i.e., the plasma potential controlling electrode 36, the magnetic filter assembly 68 and the process gas injection device 60, respectively), other arrangements are contemplated. For example, the single or double picket fence embodiments of the magnetic filter assembly could be constructed so that the lower level of the picket fence electrode is constructed to form a gas injection manifold for the injection of the process gas into the process chamber (and thereby perform the function of the process gas injection device 60). Additionally, or alternatively, the double or single picket fence could be shaped to spatially adjust the plasma. Additionally, or alternatively, the picket fence could be rotated during a plasma processing operation to make the process plasma more uniform. It is also contemplated to control the electron temperature of the process plasma by introducing a molecular species having a low excitation and ionization potential into the process plasma to absorb electron energy and to radiate energy

It is also contemplated that the plasma potential controlling electrode 36, the magnetic filter assembly 68 and the process gas injection device 60 could be constructed to be assembled to one another as a unit or module which could then be removably mounted in the reaction chamber of an ICP (or TCP) reactor as a portable module. This modular construction would allow a conventional ICP reactor to be converted for use in performing the methods of the present invention by installing the module within the reaction chamber. For example, such a module could be placed in a TCP in a position to divide the interior of the chamber into a source region and a processing region. A module may include a process gas injection device to inject a gaseous process material into the process region, a potential controlling electrode to control the potential of the source plasma, and a magnetic filter assembly operable to impose a magnetic field generally between the source region and the process region to control the flow of charged particles from the source plasma into the gaseous process material to generate a process plasma in the process region.

The many features and advantages of the present invention are apparent from the detailed specification and thus, it is intended by the appended claims to cover all such features and advantages of the described method which follow in the true spirit and scope of the invention. Further, since numerous modifications and changes will readily occur to those of ordinary skill in the art, it is not desired to limit the invention to the exact construction and operation illustrated and described. Moreover, the method and apparatus of the present invention, like related apparatus and methods used in the semiconductor arts that are complex in nature, are often best practiced by empirically determining the appropriate values of the operating parameters, or by conducting computer simulations to arrive at best design for a given application. Accordingly, all suitable modifications and equivalents should be considered as falling within the spirit and scope of the invention.

What is claimed is:

1. A plasma processing apparatus for processing a workpiece, the apparatus comprising:
a source gas injection device constructed and arranged to inject a gaseous source material into a source region of said apparatus;
a plasma generating device mounted in plasma generating relation to said source region and being constructed and arranged to transmit energy to a gaseous source material in said source region to generate a source plasma;
a process gas injection device constructed and arranged to inject a gaseous process material into a process region of said apparatus;
a magnetic filter assembly constructed and arranged to impose a magnetic field generally between said source region and said process region to control the flow of charged particles from the source plasma into the gaseous process material to generate a process plasma in said process region;
a source electrode in contact with the source plasma constructed and arranged to control the potential of the source plasma; and
a support structure constructed and arranged to support a workpiece so that the charged particles strike the workpiece.

2. A plasma processing apparatus as recited in claim 1, wherein said support structure comprises an electrode constructed and arranged to support said workpiece and to generate a potential to attract charged particles from the process plasma toward the workpiece so that the charged particles strike the workpiece.

3. A plasma processing apparatus as recited in claim 1, wherein said plasma generating device includes an inductive coil.

4. A plasma processing apparatus as recited in claim 3, wherein said inductive coil is a TCP coil mounted in plasma generating relation to the source region of said apparatus.

5. A plasma processing apparatus as recited in claim 4, wherein said plasma generating device further includes a power supply in electrical communication with said coil.

6. A plasma processing apparatus as recited in claim 3, wherein said source gas injection device is a substantially annular gas injector mounted about the periphery of said plasma TCP coil.

7. A plasma processing apparatus as recited in claim 6, wherein said process gas injection device is disposed between said magnetic filter assembly and said process region of said apparatus.

8. A plasma processing apparatus as recited in claim 1, wherein said process gas injection device includes a plurality of tubes, each tube including one or more gas outlet openings and said tubes being coupled to a source of said gaseous process material.

9. A plasma processing apparatus as recited in claim 1, wherein said magnetic filter assembly includes an array of permanent magnets.

10. A plasma processing apparatus as recited in claim 9, wherein each permanent magnet is contained within a housing made of at least one of a metal and a dielectric material.

11. A plasma processing apparatus as recited in claim 10, wherein said metal material is aluminum.

12. A plasma processing apparatus as recited in claim 1, wherein said magnetic filter assembly includes one or more electromagnets.

13. A plasma processing apparatus as recited in claim 12, wherein said magnetic filter assembly is comprised of a U-shaped electromagnet having a bight portion and a pair of leg portions extending from the bight portion, the magnetic filter assembly further including an array of permanent magnets connected to said bight portion and extending outwardly therefrom in spaced relation to the leg portions.

14. A plasma processing apparatus as recited in claim 13, said U-shaped electromagnet comprising a U-shaped yoke constructed of a magnetic flux conducting material and defining said bight and leg portions and further comprising one or more coil magnets wound around the bight portion of the electromagnet such that when each said one or more coil magnets is energized, magnetic energy is generated and conducted through said yoke.

15. A plasma processing apparatus as recited in claim 14, further comprising one or more current sources, each said one or more coil magnet being in electrical communication with a current source.

16. A plasma processing apparatus for processing a workpiece, the apparatus comprising:
a reaction chamber having an interior that defines a source region and a processing region;
a source gas injection device constructed and arranged to inject a gaseous source material into said source region of said reaction chamber;
a plasma generating device mounted to said chamber and being constructed and arranged to transmit energy to a gaseous source material in said source region to generate a source plasma;
a process gas injection device constructed and arranged to inject a gaseous process material into said process region of said reaction chamber;
a voltage source in contact with the source plasma constructed and arranged to control the potential of the source plasma;
a magnetic filter assembly constructed and arranged to impose a magnetic field generally between said source region and said process region to control the flow of charged particles from the source plasma into the gaseous process material to generate a process plasma in said process region; and
a support structure constructed and arranged to support a workpiece so that the charged particles strike the workpiece.

17. A plasma processing apparatus as recited in claim 16, said support structure comprising an electrode constructed and arranged to support the workpiece and to generate a potential to attract charged particles from the process plasma toward the workpiece so that the charged particles strike the workpiece.

18. A plasma processing apparatus as recited in claim 16, wherein said plasma generating device includes a spiral RF antenna in electrical communication with one or more RF power sources and inductively coupled to said gaseous source material.

19. A plasma processing apparatus as recited in claim 18, wherein said RF antenna is mounted on a dielectric window to facilitate transmission of energy to a gaseous source material in said source region to generate a source plasma.

20. A plasma processing apparatus as recited in claim 16, wherein said reaction chamber includes one or more grounded side wall portions at least partially surrounding said source region and said processing region.

21. A plasma processing apparatus as recited in claim 20, wherein said reaction chamber is made of a metal material.

22. A plasma processing apparatus as recited in claim 21, wherein said metal material is aluminum.

23. A plasma processing apparatus as recited in claim 16, wherein said voltage source is positioned between said source region and said magnetic filter assembly and wherein said voltage source includes a plurality of openings constructed and arranged to allow passage of charged particles from a source plasma in said source region to said processing region.

24. A plasma processing apparatus as recited in claim 23, wherein said magnetic filter assembly includes an array of permanent magnets, the array of magnets being spaced with one another so as to define a plurality of openings in said magnetic filter assembly, the openings of the magnetic filter assembly being aligned with the openings in the voltage source to allow passage of charged particles from a source plasma in said source region to said processing region.

25. A plasma processing apparatus as recited in claim 23, wherein said process gas injection device includes a plurality of gas injection tubes, each gas injection tube including one or more gas outlet openings and each tube being coupled to a source of said gaseous process material, the tubes being arranged in said reaction chamber to define a plurality of openings therebetween, said openings in said process gas injection device being generally aligned with the openings in the magnetic filter assembly and with the openings in the voltage source to allow passage of charged particles from a source plasma in said source region to said processing region.

26. A plasma processing apparatus as recited in claim 25, further comprising a cover structure constructed of silicon material mounted in said reaction chamber between said plurality of gas injection tubes and said processing region.

27. A plasma processing apparatus as recited in claim 17, wherein said electrode is in electrical communication with one or more RF power sources.

28. A plasma processing apparatus as recited in claim 17, wherein said electrode is movably mounted in said reaction chamber for movement generally toward and away from the processing region.

29. A plasma processing apparatus as recited in claim 16, wherein said reaction chamber includes a vacuum pumping port for removing gaseous material from said reaction chamber.

30. A method for processing a workpiece, the method comprising:
generating a source plasma;
providing a process gas;
controlling a flow of charged particles from the source plasma into the process gas to generate a process plasma from the process gas and to control properties of the process plasma; and
striking the workpiece with charged particles from the process plasma.

31. A method for processing a workpiece as recited in claim 30, wherein said controlling the flow of charged particles includes imposing a magnetic field between the source plasma and the process gas.

32. A method for processing a workpiece as recited in claim 31, wherein said magnetic field is of constant field strength.

33. A method for processing a workpiece as recited in claim 31, wherein the imposing is accomplished utilizing one or more permanent magnets.

34. A method for processing a workpiece as recited in claim 31, wherein the field strength of said magnetic field is variable.

35. A method for processing a workpiece as recited in claim 34, wherein the imposing is accomplished utilizing a double picket fence shield.

36. A method for processing a workpiece as recited in claim 35, wherein the double picket fence shield has a DC potential.

37. A method for processing a workpiece as recited in claim 34, wherein the imposing is accomplished utilizing a single picket fence shield.

38. A method for processing a workpiece as recited in claim 37, wherein the single picket fence shield has a DC potential.

39. A method for processing a workpiece as recited in claim 31, wherein said source plasma has a relatively high electron temperature and wherein said controlling the flow of charged particles includes utilizing said magnetic field to inhibit electrons having the relatively high electron temperature from flowing into said process gas and to allow electrons having a relatively low electron temperature to flow into said process gas.

40. A method for processing a workpiece as recited in claim 31, wherein said controlling further includes controlling said magnetic field to control the EEDF of the process plasma.

41. A method for processing a workpiece as recited in claim 31, wherein said controlling further includes controlling the potential of said source plasma.

42. A method for processing a workpiece as recited in claim 41, wherein said controlling further includes controlling the EEDF of the source plasma by controlling the potential of said source plasma.

43. A method for processing a workpiece as recited in claim 41, wherein said controlling further includes controlling the potential of said source plasma to control the energy of positive ions entering said process gas.

44. A method for processing a workpiece as recited in claim 41, wherein said controlling said potential of said source plasma is accomplished by providing a source electrode, said source electrode being electrically communicated to a controllable voltage source and having at least one surface substantially in contact with the source plasma.

45. A method for processing a workpiece as recited in claim 41, wherein the generating the source plasma comprises generating a high density source plasma utilizing an ICP coil.

46. A plasma processing apparatus for processing a workpiece, the apparatus comprising:
a reaction chamber having an interior;
a module constructed and arranged to divide said interior into a source region and a processing region;
a plasma generating device mounted to said chamber and being constructed and arranged to generate a source plasma in said source region; and
a chuck electrode constructed and arranged to support a workpiece in said processing region;
said module comprising a process gas injection device constructed and arranged to inject a gaseous process material into said process region of said reaction chamber, a potential controlling electrode constructed and arranged to control the potential of the source plasma, and a magnetic filter assembly constructed and arranged to impose a magnetic field generally between said source region and said process region to control the flow of charged particles from the source plasma into the gaseous process material to generate a process plasma in said process region.

47. The plasma processing apparatus as recited in claim 46, wherein said chuck electrode is further constructed and arranged to generate a potential to attract charged particles from the process plasma toward the workpiece so that the charged particles strike the workpiece.

48. In a plasma processing device having a reaction chamber and structure for supporting a workpiece within the reaction chamber:
a unit removably mounted in the reaction chamber constructed and arranged to divide the reaction chamber interior into a source region and a processing region; and
a plasma generating device mounted to said chamber and being constructed and arranged to generate a source plasma in said source region;
said unit comprising a process gas injection device constructed and arranged to inject a gaseous process material into said process region of said reaction chamber, a potential controlling electrode constructed and arranged to control the potential of the source plasma, and a magnetic filter assembly constructed and arranged to impose a magnetic field generally between said source region and said process region to control the flow of charged particles from the source plasma into the gaseous process material to generate a process plasma in said process region.
